(19) United States
(12) Patent Application Publication
(10) Pub. No.: US 2008/0291623 A1
(43) Pub. Date: Nov. 27, 2008

(54) ELECTRONICS PACKAGE FOR A BATTERY

(75) Inventors: Philippe GENIN, Bordeaux (FR); Jerome Calmejane, Saint Germain Du Puch (FR); Benoit Turbe, Merignac (FR)

Correspondence Address: SUGHRUE MION, PLLC, 2100 PENNSYLVANIA AVENUE, N.W., SUITE 800, WASHINGTON, DC, 20037, US

(73) Assignee: SAFT GROUPE SA, BAGNOLET (FR)

(21) Appl. No.: 11/763,076

(22) Filed: Jun. 14, 2007

(30) Foreign Application Priority Data
May 25, 2007 (FR) 0703714

(51) Int. Cl. H05K 7/20; H05K 7/00

(52) U.S. Cl. 361/688; 361/728

(57) ABSTRACT

An electronics package for a battery (1) comprises connectors (14) providing connection to internal components of the battery, an interface connector (15) with an external application, and a charging circuit (20) for the battery. The charging circuit and connectors are integrated into a same package (10) designed to be fixed to the battery. Application to a battery providing back up power.

### BACKGROUND OF THE INVENTION

The present invention relates to an electronics package for a battery comprising at least one sealed accumulator.

An electrochemical cell or accumulator (these terms are equivalent) is a device for producing electricity in which chemical energy is converted into electrical energy. The chemical energy is constituted by electrochemically active compounds deposited on at least one side of electrodes arranged inside the accumulator. Electrical energy is produced by electrochemical reactions while the accumulator is discharging. The electrodes, arranged inside a container, are electrically connected to current output terminals providing electrical continuity between the electrodes and an electrical consumer with which the accumulator is associated.

The battery is designed to supply electrical energy to an external application; a charging circuit is consequently generally provided to which the battery can be connected in order to recharge the accumulators. In order to increase output power, it is known to associate several sealed accumulators in order to form a battery. The battery then comprises one or several parallel branches of accumulators connected in series. Charge and discharge management of the battery can then be arranged and monitored in order to balance charge and discharge of the various accumulators one with respect to the others. A monitoring circuit, which is more or less elaborate depending on applications, is generally provided in order to be associated with the battery.

For applications in which batteries are used for emergency purposes, it is important that the accumulators be charged to their full capacity prior to their use, which can occur at any point in time. Now, batteries are generally connected to a charger and then disconnected from the charger in order to be connected to the application for which they are intended. Thus, a battery providing back up power can be partially discharged when demands are made on it.

In an application to aircraft, and in particular to drones, it is desirable for the emergency battery to be operational at its full capacity when needs arise.

There is consequently a need for a battery for emergency purposes which can be charge permanently while demands are not being made on it for electrical energy by an external application.

### SUMMARY OF THE INVENTION

To this end, the invention provides an electronics package designed to be fixed to the battery and which notably integrates the charging circuit. The charging circuit is no longer disassociated from the battery but rather integrated into the battery which can be charged permanently wherever it may be located. Notably, the external application can charge the battery providing back up power while the main power supply is operational.

More particularly, the invention provides an electronics package for a battery comprising:
at least one connector providing connection to internal components of the battery;
an interface connector with an external application;
a charging circuit for the battery;
the said circuit and said connectors being integrated into the same package designed to be fixed to the battery.

According to embodiments, the electronics package according to the invention call comprise one or more of the following characteristics:
the electronics package further comprises a monitoring circuit for operation of the battery;
the charging circuit and monitoring circuit are integrated into a same printed circuit board;
the interface connector comprises a power supply connector for the battery charging circuit;
the interface connector comprises a connector to a data bus;
the connector providing connection to internal components of the battery comprises connections with the current output terminals of at least one sealed accumulator of the battery;
the connector providing connection to internal components of the battery comprises connections with sensors arranged in the battery;
the connector providing connection to internal components of the battery comprises connections with heating elements arranged in the battery;
the package is of metal, for example aluminium;
the package has cooling fins;
the package is screened from the influence of electromagnetic interference.

The invention also provides a battery providing back up power comprising at least one sealed electrochemical accumulator placed in a container and an electronics package according to the invention fixed to the container.

The invention has application to the use of such a battery providing back up power for an aircraft, for example for a drone.

Further characteristics and advantages of the invention will become more clear from reading the description which follows, provided by way of example and with reference to the attached drawings.

### BRIEF DESCRIPTION OF THE DRAWINGS

FIG. 1 shows a perspective view of a battery associated with an electronics package according to the invention.

FIG. 2 is a bottom view showing the inside of the electronics package according to the invention.

### DETAILED DESCRIPTION OF PREFERRED EMBODIMENTS

The invention applies to a battery used for emergency purposes, in other words a battery designed to supply electrical power to an external application should the main source of electrical power not be operational for some reason. The invention provides an electronics package designed to be fixed to the battery and integrating notably the charging circuit for the battery. The battery used for emergency purposes according to the invention can thus be charged to its full capacity permanently, from a fixed source of electrical power or from the main power supply of the application, and while demands are not being made on the battery for back up power supply. A particular application of such a battery providing back up power can be envisaged for aircraft and notably for long-range drones which require considerable capacity; the battery providing back up power which integrates its own charger can then be charged by a source of electrical power on the ground or via the main source of electrical power of the aircraft.

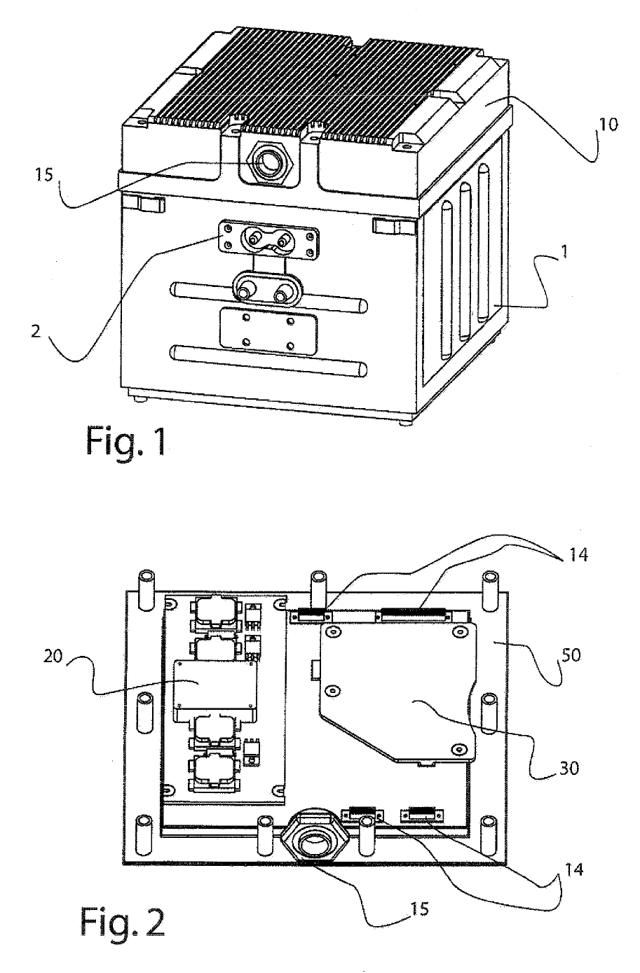

FIG. 1 shows a battery 1 with an electronics package 10 according to the invention fixed to the battery. On FIG. 1, electronics package 10 is secured to the top of the battery; it will be understood that electronics package 10 could be fastened onto a side wall of the battery without departing from the scope of the invention. In one particular embodiment, electronics package 10 constitutes a lid of the container of battery 1. The electronics package according to the invention constitutes a component that is independent of the battery; the electronics package can be rapidly and readily removed for replacement or repair. The electronics package according to the invention does nevertheless remain fixed to the battery during use, wherever the latter is located; the charge in the battery can thus be guaranteed permanently while demands are not being made on it by an external application.

The battery comprises at least one sealed accumulator and can comprise a plurality of sealed accumulators, for example two parallel branches of five to ten accumulators arranged in a container to which electronics package 10 is fixed. When the battery comprises several accumulators, it is preferable to provide a circuit monitoring operation of the battery in order to balance charge and discharge of the accumulators one with respect to the others. The electronics package according to the invention can consequently also comprise such a monitoring circuit.

FIG. 2 shows an electronics package according to the invention. Package 10 of FIG. 1 is shown open in FIG. 2.

In FIG. 2, there can be seen a support plate 50 constituting the base of the package. Package 10 is preferably made of metal and closed in a sealed manner in order to ensure protection for the monitoring electronics from electromagnetic interference which could be generated by the application to which the battery is connected. Package 10 can be made of aluminium which ensures good thermal dissipation and it can have cooling fins to aid in dissipating the thermal energy produced by the charging circuit. The fins (which can be seen in FIG. 1) can be bonded to or machined on the upper wall of package 10.

In FIG. 2 there can also be seen a mechanical holder which receives the connectors and circuits. At least one connector 14 is intended to connect the electronics circuits of the package to the internal components of the battery. An interface connector 15 is also provided. This connector is called an interface connector 15 since it is designed to be connected to an external application in order to ensure, firstly, data transfer concerning the operation of the battery and secondly, passage of current to keep the battery charged. The power connectors designed to supply electrical energy from the battery to an external application can be seen in FIG. 1 where they bear reference numeral 2 with a cover designed to be folded over onto the power connectors 2, and a fuse housing.

FIG. 2 also shows the presence of a charging circuit 20 with protective capacitors and a relay, and a monitoring circuit 30 inside the electronics package according to the invention. Charging circuit 20 and monitoring circuit 30 can be integrated into the same printed circuit or can constitute two separate circuits arranged on a support (as shown in FIG. 2). Wired connections (not shown) connect the circuits and connectors together.

Interface connector 15 comprises a power connector to allow passage of charging current from an outside power source to which connector 15 is connected, to charging circuit 20. Interface connector 15 also comprises a data connector for connection to an external data bus. According to the invention, since charging circuit is not disassociated from battery 1, interface connector 15 can alternately be connected to a utility mains or line source of power and to a main power supply of the application for which the back up battery is intended.

In FIG. 2, four connectors 14 are provided between the electronics package and the internal components of the battery, but one single connector can suffice depending on applications and the type of battery. These connectors 14 comprise connections with the power output terminals of the accumulators in order to allow charging thereof, connections to sensors arranged in the battery and connections to heating elements which can be provided between the accumulators of the battery. The connectors 14 can be filtered, notably as regards the connections to other sensors. For example, sensors can be provided in the battery in order to measure voltage, current and temperature of each accumulator. Information from the sensors is transmitted to monitoring circuit 30 and can be transmitted to the external application via interface connector 15.

The electronics package according to the invention is designed to be fixed onto a battery providing back up power. As long as the main power supply of the application which for example is a drone, is operational, the interface connector provides passage of current from the main power supply to charging circuit 20 and to the heating elements if such elements are placed in the battery. Charging of the emergency battery is thus permanently ensured.

Interface connector 15 also allows exchange of data between the battery and the external application. This information can consist in measurement of voltage, current and temperature of the accumulators of the battery and of measurement of temperature, altitude, and voltage in the drone; this information can also consist in information that has already been processed by monitoring circuit 30 for the battery, such as accumulator charge status, operating status of alarms or otherwise. Monitoring circuit 30 can thus receive, via interface connector 15, information concerning the accumulators of the battery and concerning the application itself, it can thus control activation of the heating elements for example if the temperature in the drone is below a given value as a result of altitude. Further, monitoring circuit 30 can be parameterized from interface connector 15, in other words parameterized by a central unit of the application. The emergency battery can then be specifically parameterized or re-parameterized by the application with which it is associated.

The embodiments described above and the drawings should be considered as being simply illustrative and not restricting, and the invention is not intended to be limited to the details provided here but can be modified while still remaining within the scope of the attached claims. In particular, the invention concerns any type of battery accumulator whether it is prismatic, cylindrical or concentric; or whether it is of the lithium ion, nickel cadmium or nickel metal hydride type.

1. An electronics package for a battery comprising:
at least one connector providing connection to internal components of the battery;
an interface connector with an external application;
a charging circuit for the battery;
the said circuit and said connectors being integrated into a same package (10) designed to be fixed to the battery.

2. The electronics package according to claim 1, further comprising a monitoring circuit for operation of the battery.

3. The electronics package according to claim 2, in which the charging circuit and monitoring circuit are integrated into a same printed circuit board.

4. The electronics package according to claim 1, in which the interface connector comprises a connector powering the charging circuit for the battery.

5. The electronics package according to claim 1, in which the interface connector comprises a connector to a data bus.

6. The electronics package according to claim l, in which the connector providing connection to internal components of the battery comprises connections with the current output terminals of at least one sealed accumulator of the battery.

7. The electronic package according to claim 6, in which the connector providing connection to internal components of the battery comprises connections with sensors arranged in the battery.

8. The electronics package according to claim 7, in which the connector providing connection to intern al components of the battery comprises connections with heating elements arranged in the battery.

9. The electronics package according to claim 1, in which the package is of metal.

10. The electronics package according to claim 9, in which the package is of aluminium.

11. The electronics package according to claim 9, in which the package has cooling fans.

12. The electronics package according to claim 9, in which the package is screened from the influence of electromagnetic interference.

13. A battery providing back up power comprising at least one sealed electrochemical accumulator placed in a container and an electronics package fixed to said container, side electronic package comprising:
at least one connector providing connection to internal components of the battery;
an interface connector with an external application;
a charging circuit for the battery.

14. The use of the battery of claim 13 to provide back up power for an aircraft.

15. The use of the battery of claim 13 to provide back up power for a drone.
